(19) United States
(12) Patent Application Publication
(10) Pub. No.: US 2026/0262523 A1
(43) Pub. Date: Sep. 3, 2026

(54) SEMICONDUCTOR DEVICE

(71) Applicant: FUJI ELECTRIC CO., LTD., Kanagawa (JP)

(72) Inventor: Hideo AMI, Matsumoto-city (JP)

(21) Appl. No.: 19/654,478

(22) Filed: Apr. 22, 2026

Related U.S. Application Data
(63) Continuation of application No. PCT/JP2025/014159, filed on Apr. 9, 2025.

(30) Foreign Application Priority Data
May 30, 2024 (JP) 2024-087654

(51) Int. Cl. H10W 70/654; H10W 70/65; H10W 90/00; H10W 90/10

(52) U.S. Cl. CPC H10W 70/654; H10W 70/658; H10W 90/10; H10W 90/701; H10W 90/754

(57) ABSTRACT

Provided is a semiconductor device comprising: an insulating plate; a semiconductor element provided above the insulating plate and having a first control electrode and a second control electrode; a plurality of first conductive patterns provided above the insulating plate and electrically connected to the first control electrode; and a plurality of second conductive patterns provided above the insulating plate and electrically connected to the second control electrode, wherein the plurality of first conductive patterns and the plurality of second conductive patterns are alternately arranged in a predetermined arrangement direction, the plurality of first conductive patterns are electrically connected to each other, and the plurality of second conductive patterns are electrically connected to each other.

### BACKGROUND

### 1. TECHNICAL FIELD

The present invention relates to a semiconductor device.

### 2. RELATED ART

Patent Document 1 describes a semiconductor module.

### RELATED ART DOCUMENTS

### PATENT DOCUMENTS

Patent Document 1: Japanese Patent Application Publication No. 2024-013924

Patent Document 2: International Publication No. 2023/037809

### BRIEF DESCRIPTION OF THE DRAWINGS

FIG. 1A shows an example of a perspective view of a semiconductor device 100.

FIG. 1B shows an example of the plan view of the semiconductor device 100.

FIG. 1C shows an example of a region R of the semiconductor device 100.

FIG. 2 shows an example of the region R of semiconductor device 500 according to a comparative example.

FIG. 3A shows an example of a main current fluctuation in the semiconductor device 100.

FIG. 3B shows an example of a main current fluctuation in semiconductor device 500 according to a comparative example.

FIG. 4A shows an example of a magnetic flux interlinkage in the semiconductor device 100.

FIG. 4B shows an example of a magnetic flux interlinkage in semiconductor device 500 according to a comparative example.

FIG. 5 shows the region R of a modification example of the semiconductor device 100.

FIG. 6 shows the region R of the modification example of the semiconductor device 100.

FIG. 7 shows the region R of the modification example of the semiconductor device 100.

### DESCRIPTION OF EXEMPLARY EMBODIMENTS

The present invention will be described below through embodiments of the invention, but the following embodiments do not limit the invention according to the claims. In addition, not all of the combinations of features described in the embodiments are essential to the solving means of the invention.

In the present specification, one side in a direction parallel to a depth direction of a semiconductor substrate included in a semiconductor chip is referred to as an "upper" side, and another side is referred to as a "lower" side. One surface of two principal surfaces of a substrate, a layer or other member is referred to as an upper surface, and the other surface is referred to as a lower surface. “Upper”, “lower”, “front”, and “back” directions are not limited to a direction of gravity, or a direction of an attachment to a substrate or the like when a semiconductor device is mounted.

In the present specification, technical matters may be described using orthogonal coordinate axes consisting of an X axis, a Y axis, and a Z axis. In the present specification, a surface parallel to an upper surface of the semiconductor chip is referred to as an XY surface, and the depth direction of the semiconductor substrate included in the semiconductor chip is referred to as the Z axis.

When a term such as “same” or “equal” is used in the present specification, it may encompass a case where an error due to a variation in manufacturing or the like is included. The error is, for example, within 10%.

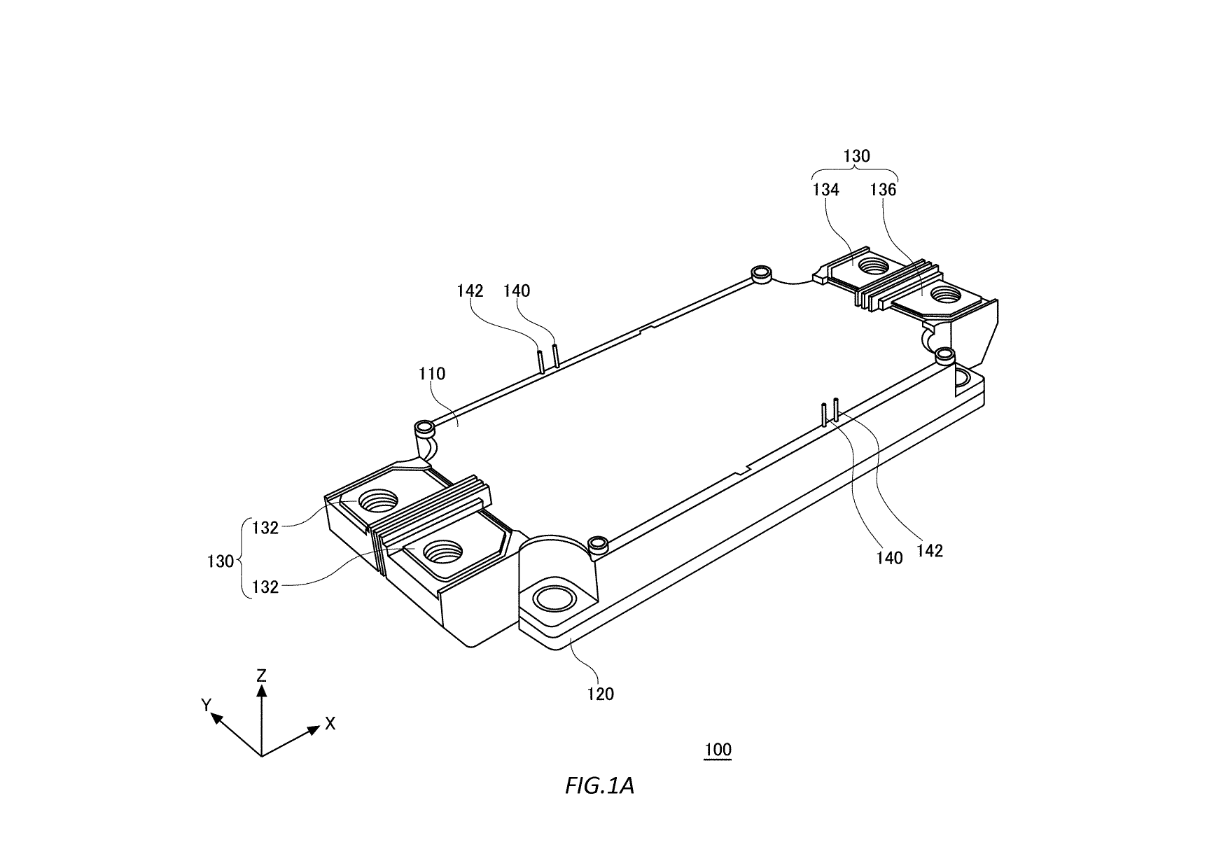

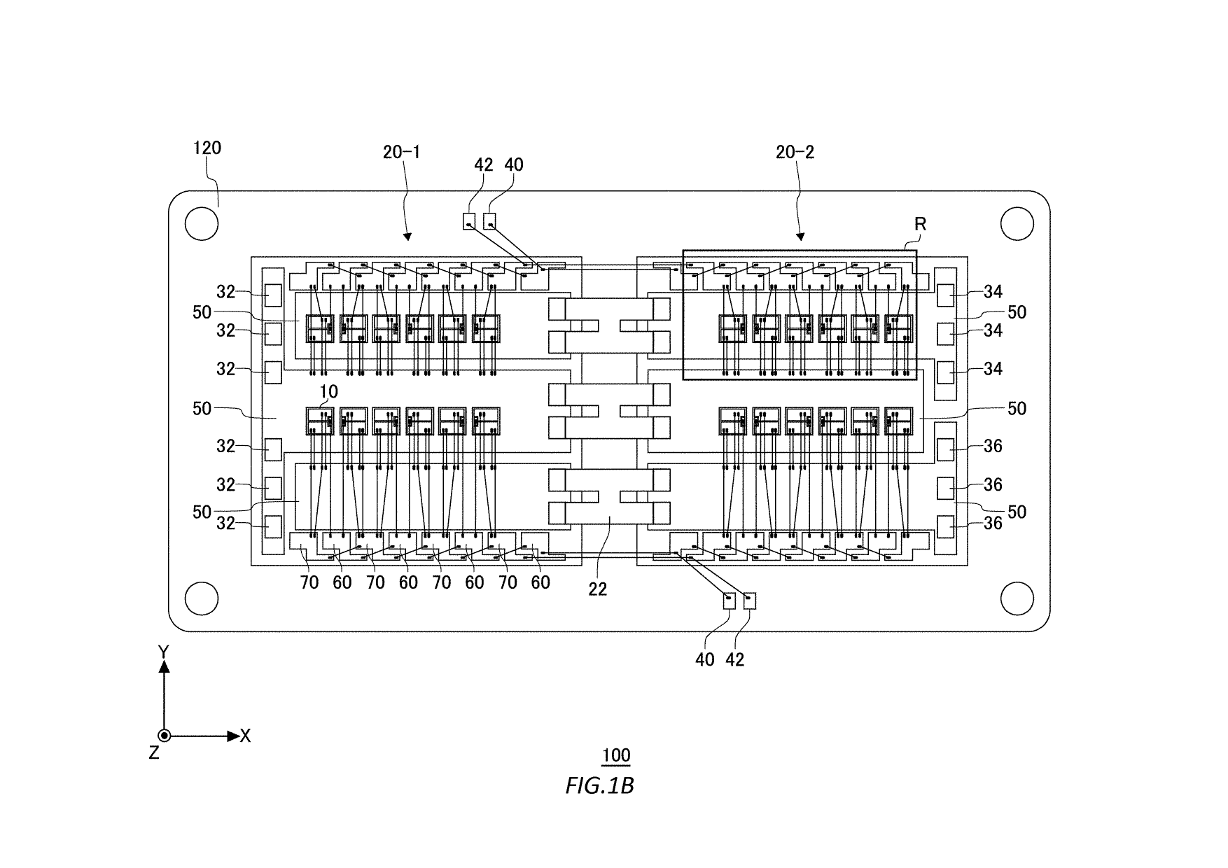

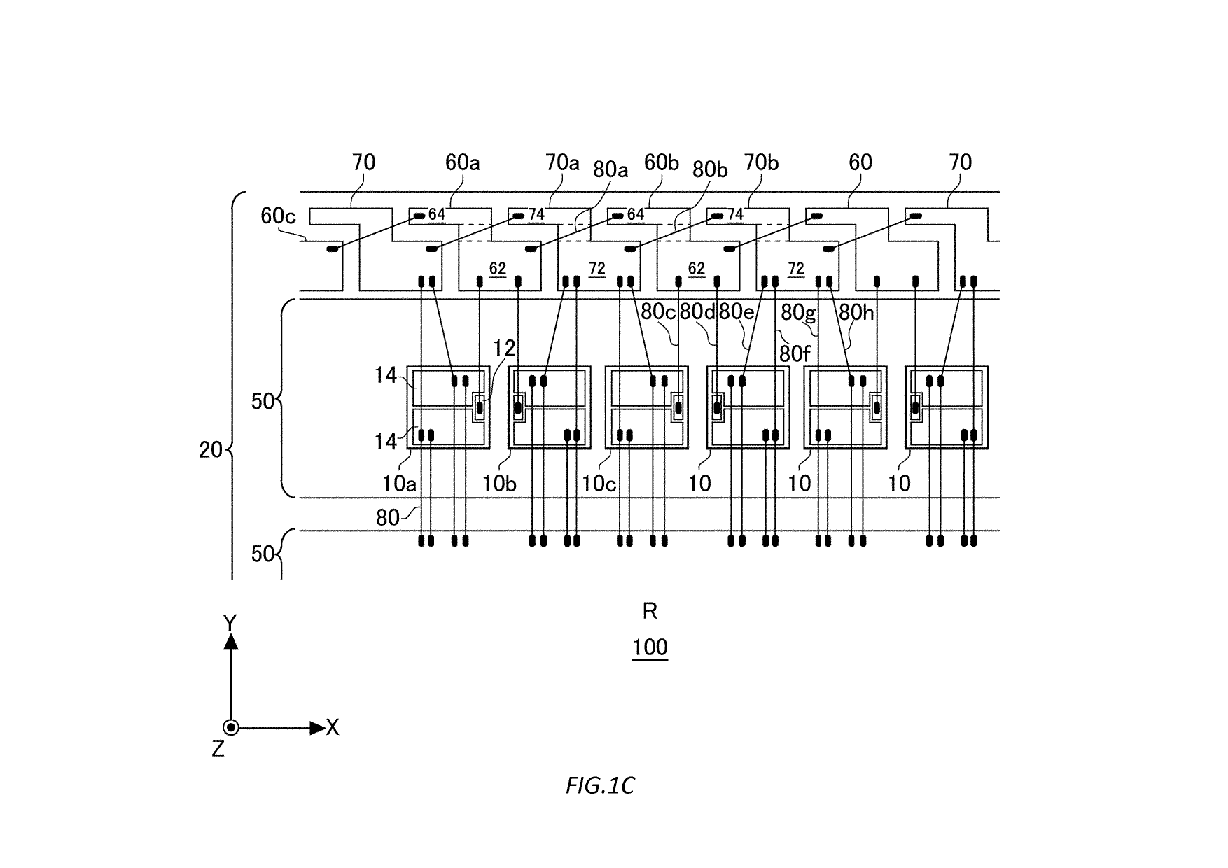

FIG. 1A shows an example of a perspective view of the semiconductor device 100. The semiconductor device 100 includes a casing portion 110, a base portion 120, and a plurality of terminals. The semiconductor device 100 may function as a part of the power conversion device such as an inverter. The semiconductor device 100 may house a semiconductor chip and the like therein.

The casing portion 110 houses the semiconductor chip and the like included in the semiconductor device 100. The casing portion 110 is molded of resin with insulation properties. The casing portion 110 is provided on the base portion 120.

The base portion 120 is fixed to the casing portion 110 with a screw, an adhesive, or the like. The casing portion 110 may be provided with a hole portion for fixing the base portion 120. The base portion 120 may be set to a ground potential. The base portion 120 has a principal surface in an XY plane.

On the upper surface side of the casing portion 110, a plurality of terminals may be provided. On the upper surface side of the casing portion 110 of the present example, an external main terminal 130, a first external control terminal 140, and a second external control terminal 142 are provided. The external main terminal 130 may include an external output terminal 132, an external positive electrode terminal 134, and an external negative electrode terminal 136. The external output terminal 132, the external positive electrode terminal 134, and the external negative electrode terminal 136 may form the current path of a heavy current flowing through the power semiconductor element.

The external output terminal 132 is an alternating current output terminal. The external positive electrode terminal 134 is a positive side terminal of a direct current power supply. The external negative electrode terminal 136 is a negative side terminal of the direct current power supply. Each terminal may be electrically connected to a corresponding terminal of the semiconductor chip or the like included in the semiconductor device 100.

The first external control terminal 140 is a terminal that supplies a first control signal to a semiconductor element 10 which will be described later. The second external control terminal 142 is a terminal that supplies the second control signal to the semiconductor element 10. The first control signal and the second control signal will be described later.

FIG. 1B shows an example of the plan view of the semiconductor device 100. This figure shows an arrangement example of a circuit provided on the base portion 120 inside the casing portion 110. The semiconductor device 100 includes one or more insulating plates 20 on the base portion 120.

The semiconductor device 100 of the present example includes two insulating plates 20 on the base portion 120. In the present example, the two insulating plates 20 are arranged side by side in the X axis direction on the base portion 120. On an insulating plate 20, a plurality of semiconductor elements 10 and a plurality of wiring patterns may be arranged. The plurality of insulating plates 20 may be connected via a lead frame 22. In the present example, the plurality of insulating plates 20 is arranged on the base portion 120, but one insulating plate 20 may be arranged on the base portion 120.

The insulating plate 20 is bonded to the base portion 120. The insulating plate 20 may have conductive patterns on both surfaces of the ceramic (e.g., alumina) substrate having high thermal conductivity. For example, the insulating plate 20 is a Direct Copper Bond (DCB) substrate in which a copper circuit plate is directly bonded onto the ceramic substrate. Each of the insulating plates 20 is connected in parallel.

On the base portion 120, a first connection portion 40 and a second connection portion 42 may be provided. The first connection portion 40 is connected to the first external control terminal 140. The second connection portion 42 is connected to the second external control terminal 142.

The insulating plate 20 may have an output terminal 32, a positive electrode terminal 34, and a negative electrode terminal 36. In the semiconductor device 100 of the present example, the insulating plate 20-1 has the output terminal 32, and the insulating plate 20-2 has the positive electrode terminal 34 and the negative electrode terminal 36. It should be, however, noted that each of the insulating plates 20 of the semiconductor device 100 may have the output terminal 32, the positive electrode terminal 34, and the negative electrode terminal 36.

Each terminal may be electrically connected to each external terminal via a connection member such as the lead frame. The output terminal 32 is electrically connected to the external output terminal 132. The positive electrode terminal 34 is electrically connected to the external positive electrode terminal 134. The negative electrode terminal 36 is electrically connected to the external negative electrode terminal 136.

Above the insulating plate 20, a main conductive pattern 50, a plurality of first conductive patterns 60, and a plurality of second conductive patterns 70 are provided. The main conductive pattern 50 is a conductive pattern which is provided between the insulating plate 20 and the semiconductor element 10 and carries the main current of the semiconductor element 10. In the main conductive pattern 50, the output terminal 32, the positive electrode terminal 34, and the negative electrode terminal 36 are provided. Therefore, the main conductive pattern 50 may be electrically connected to each of the external output terminal 132, the external positive electrode terminal 134, and the external negative electrode terminal 136. That is, the external main terminal 130 may be electrically connected to the main conductive pattern 50 which carries the main current of the semiconductor element 10. Respective main conductive patterns 50 of the plurality of insulating plates 20 may be electrically connected to each other via the lead frame 22.

The plurality of first conductive patterns 60 are electrically connected to each other. The plurality of first conductive patterns 60 may be electrically connected to the first connection portion 40. That is, the first external control terminal 140 may be electrically connected to the plurality of first conductive patterns 60.

The plurality of second conductive patterns 70 are electrically connected to each other. The plurality of second conductive patterns 70 may be electrically connected to the second connection portion 42. That is, the second external control terminal 142 may be electrically connected to the plurality of second conductive patterns 70.

The semiconductor element 10 is provided above the insulating plate 20. The semiconductor element 10 may be provided above the main conductive pattern 50. The semiconductor element 10 may be the power semiconductor element. For example, the semiconductor element 10 may be an IGBT or may be a MOSFET. The semiconductor element 10 may include the wide bandgap semiconductor. As an example, the wide bandgap semiconductor includes any one of a silicon carbide semiconductor, the gallium nitride semiconductor, or the gallium oxide semiconductor. As another example, the wide bandgap semiconductor may include diamond.

FIG. 1C shows an example of the region R of the semiconductor device 100. The region R is a region shown in FIG. 1B.

The semiconductor element 10 has a first control electrode 12 and a second control electrode 14. For example, when the semiconductor element 10 is an IGBT, the first control electrode 12 may be the base electrode, and the second control electrode 14 may be the emitter electrode. As another example, when the semiconductor element 10 is a MOSFET, the first control electrode 12 may be the gate electrode, and the second control electrode 14 may be the source electrode. The semiconductor element 10 of the present example has one first control electrode 12 and two second control electrodes 14 separated from each other, but a number of at least one electrode included in the semiconductor element 10 and the arrangement thereof are not limited to the present example.

The plurality of first conductive patterns 60 are electrically connected to the first control electrode 12. The plurality of first conductive patterns 60 may be electrically connected to the first control electrode 12 via a wire member 80. As described above, the plurality of first conductive patterns 60 are electrically connected to each other, the plurality of first conductive patterns 60 are electrically connected to the first connection portion 40, and the first external control terminal 140 is electrically connected to the plurality of first conductive patterns 60. As a result of the first control signal being input from the first external control terminal 140 to the first control electrode 12, the semiconductor element 10 is controlled.

The plurality of second conductive patterns 70 are electrically connected to the second control electrode 14. The plurality of second conductive patterns 70 may be electrically connected to the second control electrode 14 via the wire member 80. As described above, the plurality of second conductive patterns 70 are electrically connected to each other, the plurality of second conductive patterns 70 are electrically connected to the second connection portion 42, and the second external control terminal 142 is electrically connected to the plurality of second conductive patterns 70. As a result of the second control signal being input from the second external control terminal 142 to the second control electrode 14, the semiconductor element 10 is controlled.

The plurality of first conductive patterns 60 and the plurality of second conductive patterns 70 are alternately arranged in a predetermined arrangement direction. The first conductive patterns 60 and the second conductive patterns 70 of the present example are alternately arranged in the X axis direction. That is, the arrangement direction of the present example is the X axis direction.

In the semiconductor device 100 of the present example, the first conductive patterns 60 and the second conductive patterns 70 are alternately arranged in a predetermined arrangement direction (for example, the X axis direction), and therefore, in a direction perpendicular to the arrangement direction (for example, the Y axis direction), distances between the respective conductive patterns and the semiconductor element 10 can be made substantially the same. This makes it possible to minimize the lengths of both: the wire member 80 connecting a first conductive pattern 60 and the first control electrode 12; and the wire member 80 connecting a second conductive pattern 70 and the second control electrode 14. Therefore, it is possible to reduce parasitic inductances of both the current path for controlling the first control electrode 12 and the current path for controlling the second control electrode 14.

Two adjacent first conductive patterns 60 may be connected to each other across the second conductive pattern 70 located between the two adjacent first conductive patterns 60. For example, a first conductive pattern 60a and a first conductive pattern 60b adjacent to each other are connected to each other across a second conductive pattern 70a located between the first conductive pattern 60a and the first conductive pattern 60b.

The plurality of first conductive patterns 60 may be electrically connected to each other via the wire member 80. The wire member 80 that electrically connects the plurality of first conductive patterns 60 to each other may connect two adjacent first conductive patterns 60 by passing above the second conductive pattern 70 located between the two adjacent first conductive patterns 60. For example, a wire member 80a that electrically connects the first conductive pattern 60a and the first conductive pattern 60b adjacent to each other connects the first conductive pattern 60a and the first conductive pattern 60b by passing above the second conductive pattern 70a located between the first conductive pattern 60a and the first conductive pattern 60b.

Two adjacent second conductive patterns 70 may be connected to each other across the first conductive pattern 60 located between the two adjacent second conductive patterns 70. For example, the second conductive pattern 70a and a second conductive pattern 70b adjacent to each other are connected to each other across the first conductive pattern 60b located between the second conductive pattern 70a and the second conductive pattern 70b.

The plurality of second conductive patterns 70 may be electrically connected to each other via the wire member 80. The wire member 80 that electrically connects the plurality of second conductive patterns 70 to each other may connect two adjacent second conductive patterns 70 by passing above the first conductive pattern 60 located between the two adjacent second conductive patterns 70. For example, a wire member 80b that electrically connects the second conductive pattern 70a and the second conductive pattern 70b adjacent to each other connects the second conductive pattern 70a and the second conductive pattern 70b by passing above the first conductive pattern 60b located between the second conductive pattern 70a and the second conductive pattern 70b.

In the semiconductor device 100 of the present example, first conductive patterns 60 are connected across the second conductive pattern 70, and second conductive patterns 70 are connected across the first conductive pattern 60. As a result, the control signal path including the plurality of first conductive patterns 60 and the control signal path including the plurality of second conductive patterns 70 form a twisted-wire-like current path. As a result of the respective control signal paths forming the twisted-wire-like current path, when magnetic flux interlinks with the control signal path, induced electromotive forces cancel each other out within the control signal path, thereby making it possible to suppress an influence of a magnetic flux interlinkage. Details of suppression of the influence of the magnetic flux interlinkage by the twisted-wire-like current path will be described later.

The main conductive pattern 50 may be provided to extend in an arrangement direction of the first conductive patterns 60 and the second conductive patterns 70. The main conductive pattern 50 of the present example is provided to extend in the X axis direction. The plurality of first conductive patterns 60 and the plurality of second conductive patterns 70 may be adjacent to the main conductive pattern 50 in a direction orthogonal to the arrangement direction. In the present example, the plurality of first conductive patterns 60 and the plurality of second conductive patterns 70 are adjacent to the main conductive pattern 50 in the Y axis direction.

In the semiconductor device 100 of the present example, the main conductive pattern 50 is provided to extend in the arrangement direction of first conductive patterns 60 and second conductive patterns 70, and first conductive patterns 60 and second conductive patterns 70 are provided adjacent to the main conductive pattern 50 in the direction orthogonal to the arrangement direction. This makes it possible to suppress an imbalance between back electromotive forces generated in the control signal path including the plurality of first conductive patterns 60 and in the control signal path including the plurality of second conductive patterns 70 due to fluctuations in the main current flowing through the main conductive pattern 50. By suppressing the imbalance between the back electromotive forces, an imbalance in a potential difference between the first control electrode 12 of the semiconductor element 10 and the second control electrode 14 can be suppressed. Details of suppression of the imbalance between the back electromotive forces due to the positional relationship of the respective conductive patterns will be described later.

At least one of the plurality of first conductive patterns 60 may have a first wiring portion 62 and a second wiring portion 64. In the semiconductor device 100 of the present example, each of the first conductive patterns 60 has first wiring portion 62 and second wiring portion 64.

On the first wiring portion 62, the wire member 80 for connection to the first control electrode 12 may be routed. On the second wiring portion 64, the wire member 80 for connection to another first conductive pattern 60 may be routed. For example, on the first wiring portion 62 of the first conductive pattern 60b, wire members 80c and 80d for connection to the first control electrode 12 are routed. On the second wiring portion 64 of the first conductive pattern 60b, the wire member 80a for connection to the first conductive pattern 60a, which is another first conductive pattern 60, is routed.

The area of the second wiring portion 64 may be smaller than the area of the first wiring portion 62. The first wiring portion 62 may be closer to the semiconductor element 10 than the second wiring portion 64 is, in the direction orthogonal to the arrangement direction. In the present example, the first wiring portion 62 is closer to the semiconductor element 10 than the second wiring portion 64 is, in the Y axis direction.

Each of two adjacent first conductive patterns 60 may have the first wiring portion 62 and the second wiring portion 64. For example, each of the first conductive pattern 60a and the first conductive pattern 60b adjacent to each other has the first wiring portion 62 and the second wiring portion 64. The wire member 80 for connection to another first conductive pattern 60 may connect the second wiring portion 64 of one of two adjacent first conductive patterns 60 to the first wiring portion 62 of another of the two adjacent first conductive patterns 60. In the present example, the wire member 80a connects the second wiring portion 64 of the first conductive pattern 60b and the first wiring portion 62 of the first conductive pattern 60a.

At least one of the plurality of second conductive patterns 70 may have a third wiring portion 72 and a fourth wiring portion 74. In the semiconductor device 100 of the present example, each of the second conductive patterns 70 has the third wiring portion 72 and the fourth wiring portion 74.

On the third wiring portion 72, the wire member 80 for connection to the second control electrode 14 may be routed. On the fourth wiring portion 74, the wire member 80 for connection to another second conductive pattern 70 may be routed. For example, on the third wiring portion 72 of the second conductive pattern 70b, wire members 80e to 80h for connection to the second control electrode 14 are routed. On the fourth wiring portion 74 of the second conductive pattern 70b, the wire member 80b for connection to the second conductive pattern 70a, which is another second conductive pattern 70, is routed.

The area of the fourth wiring portion 74 may be smaller than the area of the third wiring portion 72. The third wiring portion 72 may be closer to the semiconductor element 10 than the fourth wiring portion 74 is, in the direction orthogonal to the arrangement direction. In the present example, the third wiring portion 72 is closer to the semiconductor element 10 than the fourth wiring portion 74 is, in the Y axis direction.

Each of two adjacent second conductive patterns 70 may have the third wiring portion 72 and the fourth wiring portion 74. For example, each of the second conductive pattern 70a and the second conductive pattern 70b adjacent to each other has the third wiring portion 72 and the fourth wiring portion 74. The wire member 80 for connection to another second conductive pattern 70 may connect the fourth wiring portion 74 of one of two adjacent second conductive patterns 70 to the third wiring portion 72 of another of the two adjacent second conductive patterns 70. In the present example, the wire member 80b connects the fourth wiring portion 74 of the second conductive pattern 70b and the third wiring portion 72 of the second conductive pattern 70a.

As described above, in the semiconductor device 100 of the present example, each of the first conductive patterns 60 and the second conductive patterns 70 has the wiring portion on which the wire member 80 for connection to the control electrode of the semiconductor element 10 is routed and the wiring portion on which the wire member 80 for connection to another conductive pattern is routed. This makes it possible to improve bondability of the wire member 80 while reducing the space of a region in which the first conductive pattern 60 and the second conductive pattern 70 are arranged.

In order to improve the bondability of the wire member 80, it is preferable to ensure a bonding area of at least a certain value in the extending direction of the wire member 80. In the semiconductor device 100 of the present example, an extending direction of portions at which the wire members 80 for respectively connecting the first conductive patterns 60 to each other and the second conductive patterns 70 to each other are bonded is the arrangement direction of the first conductive pattern 60 and the second conductive pattern 70, and therefore, it is possible to reduce the bonding area in the direction orthogonal to the arrangement direction. That is, it is possible to reduce the areas of the second wiring portion 64 and the fourth wiring portion 74. This makes it possible to improve the bondability of the wire member 80 while reducing the space by shortening a length in the direction orthogonal to the arrangement direction.

The semiconductor element 10 may include a plurality of semiconductor elements 10 arranged in the arrangement direction. Two adjacent semiconductor elements 10 may be mirror-symmetrical with respect to the direction orthogonal to the arrangement direction. For example, a semiconductor element 10a and a semiconductor element 10b adjacent to each other are mirror-symmetrical with respect to the Y axis direction. The semiconductor element 10b and a semiconductor element 10c adjacent to each other are mirror-symmetrical with respect to the Y axis direction. In this manner, in the semiconductor device 100 of the present example, the semiconductor elements 10 that are mirror-symmetrical to each other are alternately arranged.

The plurality of first conductive patterns 60 may include the first conductive pattern 60 to which two semiconductor elements 10 are connected. For example, the plurality of first conductive patterns 60 include the first conductive pattern 60a to which the semiconductor element 10a and the semiconductor element 10b are connected. The plurality of second conductive patterns 70 may include the second conductive pattern 70 to which two semiconductor elements 10 are connected. For example, the plurality of second conductive patterns 70 include the second conductive pattern 70a to which the semiconductor element 10b and the semiconductor element 10c are connected.

The plurality of first conductive patterns 60 may include the first conductive pattern 60 that is connected to an adjacent first conductive pattern 60 but is not connected to the semiconductor element 10. For example, the plurality of first conductive patterns 60 include a first conductive pattern 60c that is connected to an adjacent first conductive pattern 60a but is not connected to the semiconductor element 10. Although not illustrated in the present example, similarly, the plurality of second conductive patterns 70 may include the second conductive pattern 70 that is connected to an adjacent second conductive pattern 70 but is not connected to the semiconductor element 10.

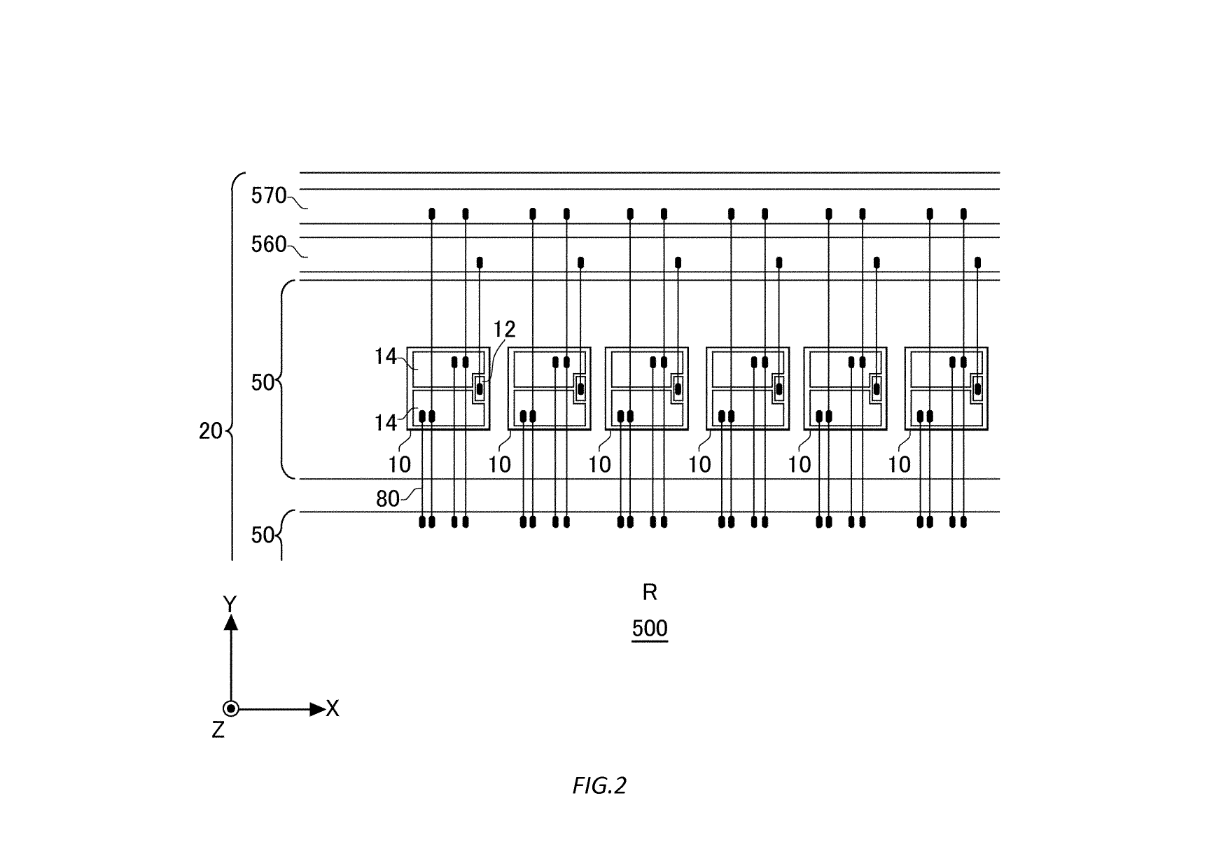

FIG. 2 shows an example of the region R of the semiconductor device 500 according to a comparative example. In the semiconductor device 500, the first control pattern 560 and the second control pattern 570 extending in an extending direction of the main conductive pattern 50 are provided.

In the semiconductor device 500 according to the comparative example, both the first control pattern 560 and the second control pattern 570 are provided to extend, and therefore, one of them is adjacent to the semiconductor element 10, and another is not adjacent to the semiconductor element 10. In the example of FIG. 2, the first control pattern 560 is adjacent to the semiconductor element 10, and the second control pattern 570 is not adjacent to the semiconductor element 10. According to such an arrangement, the wire member 80 for connection to the second control pattern 570 on a side farther from the semiconductor element 10 is longer than the wire member 80 for connection to the first control pattern 560 on a side closer to the semiconductor element 10. As a result, it may not be possible to reduce parasitic inductance of the current path for controlling the second control electrode 14.

On the other hand, according to the semiconductor device 100 according to the example, the first conductive patterns 60 and the second conductive patterns 70 are alternately arranged in a predetermined arrangement direction (for example, the X axis direction), and therefore, in a direction perpendicular to the arrangement direction (for example, the Y axis direction), distances between the respective conductive patterns and the semiconductor element 10 can be made substantially the same. This makes it possible to minimize the lengths of both: the wire member 80 connecting the first conductive pattern 60 and the first control electrode 12; and the wire member 80 connecting the second conductive pattern 70 and the second control electrode 14. Therefore, it is possible to reduce parasitic inductances of both the current path for controlling the first control electrode 12 and the current path for controlling the second control electrode 14.

In the semiconductor device 500 according to the comparative example, both the first control pattern 560 and the second control pattern 570 are provided to extend. In this case, in order to improve bondability of the wire members 80 for connecting the respective control patterns to the control electrodes of the semiconductor element 10, a width of each control pattern in a direction orthogonal to the extending direction needs to be at least a certain value. As a result, it may not be possible to achieve both improved bondability of the wire members 80 and space saving.

On the other hand, according to the semiconductor device 100 according to the example, each of the first conductive patterns 60 and the second conductive patterns 70 has the wiring portion on which the wire member 80 for connection to the control electrode of the semiconductor element 10 is routed and the wiring portion on which the wire member 80 for connection to another conductive pattern is routed. This makes it possible to improve bondability of the wire member 80 while reducing the space of a region in which the first conductive pattern 60 and the second conductive pattern 70 are arranged.

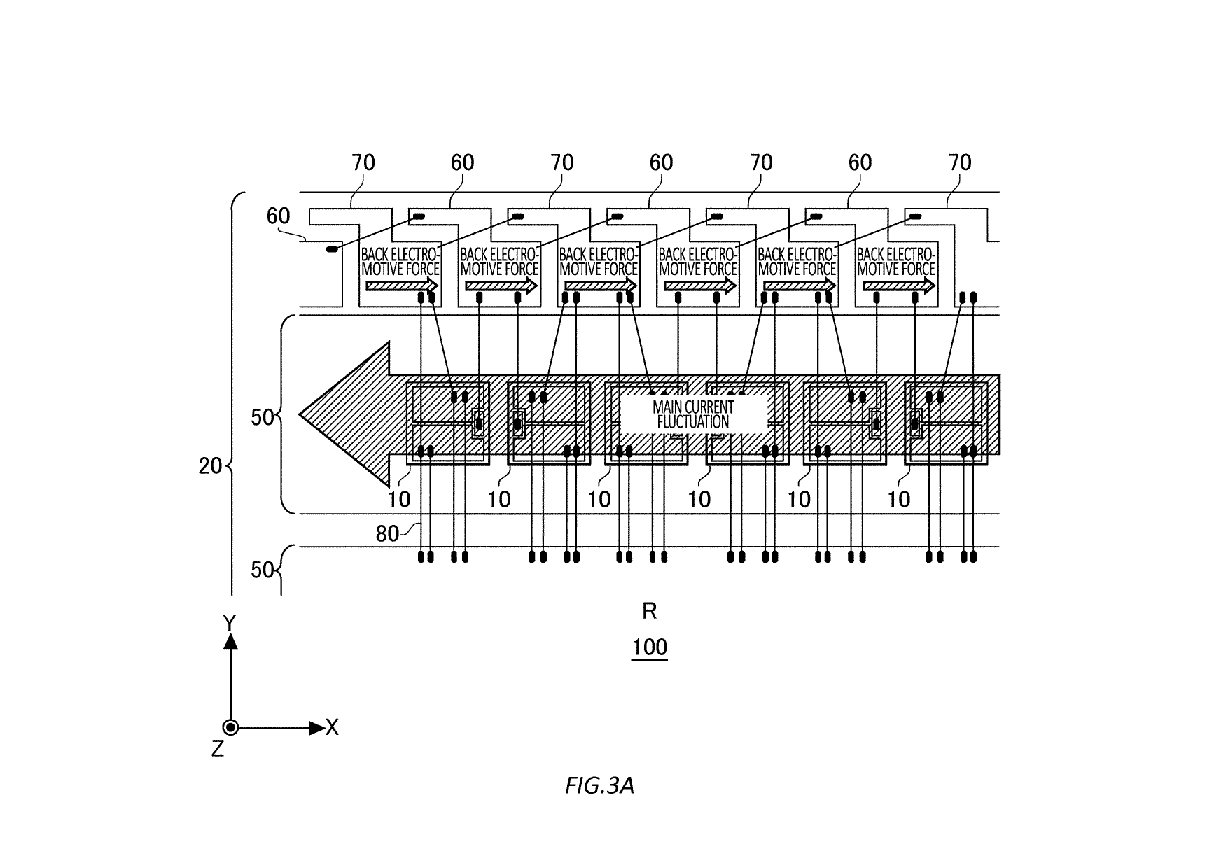

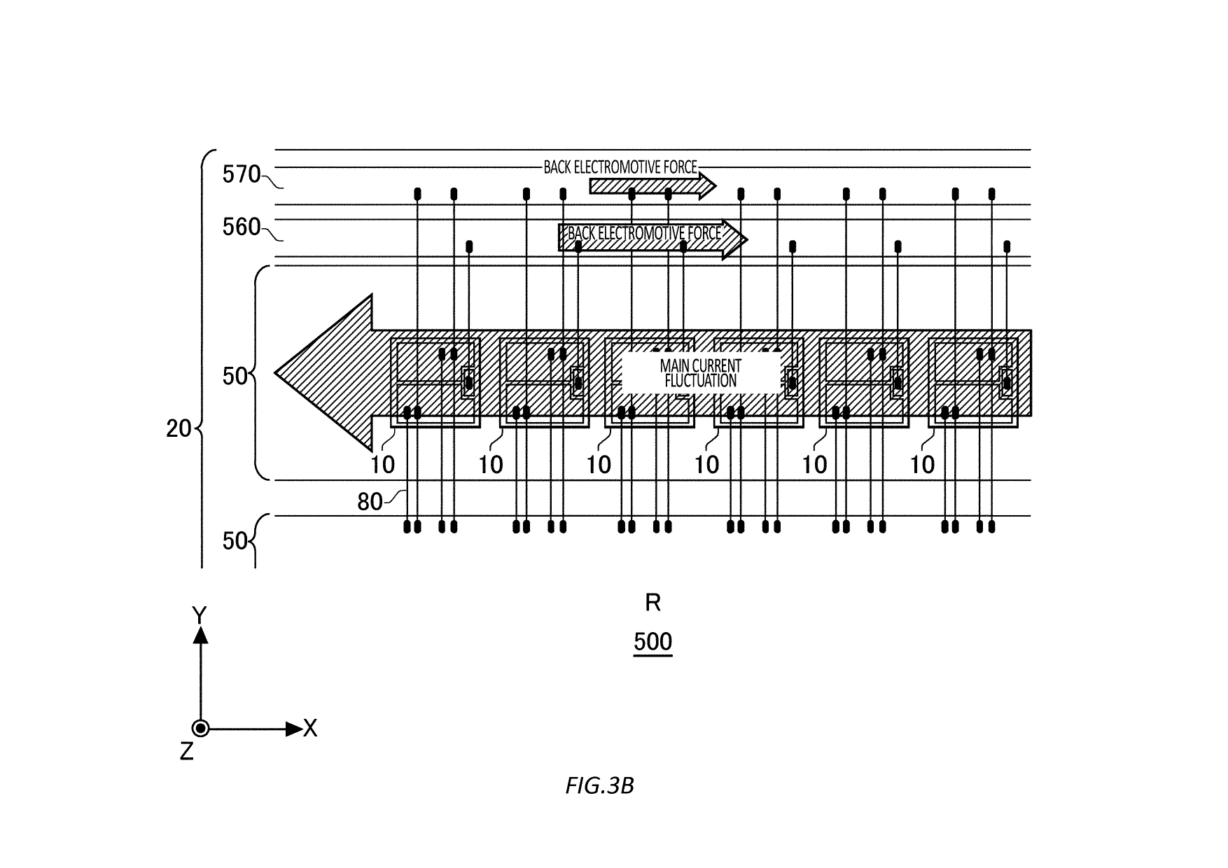

FIG. 3A shows an example of a main current fluctuation in the semiconductor device 100. For example, when the main current fluctuation in a -X axis direction occurs in the main conductive pattern 50, a back electromotive force in a +X axis direction is generated in each of the first conductive patterns 60 and the second conductive patterns 70.

In the semiconductor device 100 of the present example, the main conductive pattern 50 is provided to extend in the arrangement direction of first conductive patterns 60 and second conductive patterns 70, and first conductive patterns 60 and second conductive patterns 70 are provided adjacent to the main conductive pattern 50 in the direction orthogonal to the arrangement direction. As a result, back electromotive forces having substantially a same magnitude are generated in the first conductive pattern 60 and the second conductive pattern 70. Therefore, the imbalance in the potential difference between the first control electrode 12 of the semiconductor element 10 and the second control electrode 14 can be suppressed.

FIG. 3B shows an example of a main current fluctuation in the semiconductor device 500 according to a comparative example. For example, when the main current fluctuation in the -X axis direction occurs in the main conductive pattern 50, a back electromotive force in the +X axis direction is generated in each of the first control pattern 560 and the second control pattern 570.

In the semiconductor device 500 according to the comparative example, one of the first control pattern 560 and the second control pattern 570 is adjacent to the semiconductor element 10, and another is not adjacent to the semiconductor element 10. In the example of FIG. 3B, the first control pattern 560 is adjacent to the semiconductor element 10, and the second control pattern 570 is not adjacent to the semiconductor element 10. According to such an arrangement, a back electromotive force generated in the first control pattern 560 is greater than a back electromotive force generated in the second control pattern 570. Therefore, the imbalance in the potential difference between the first control electrode 12 of the semiconductor element 10 and the second control electrode 14 may occur.

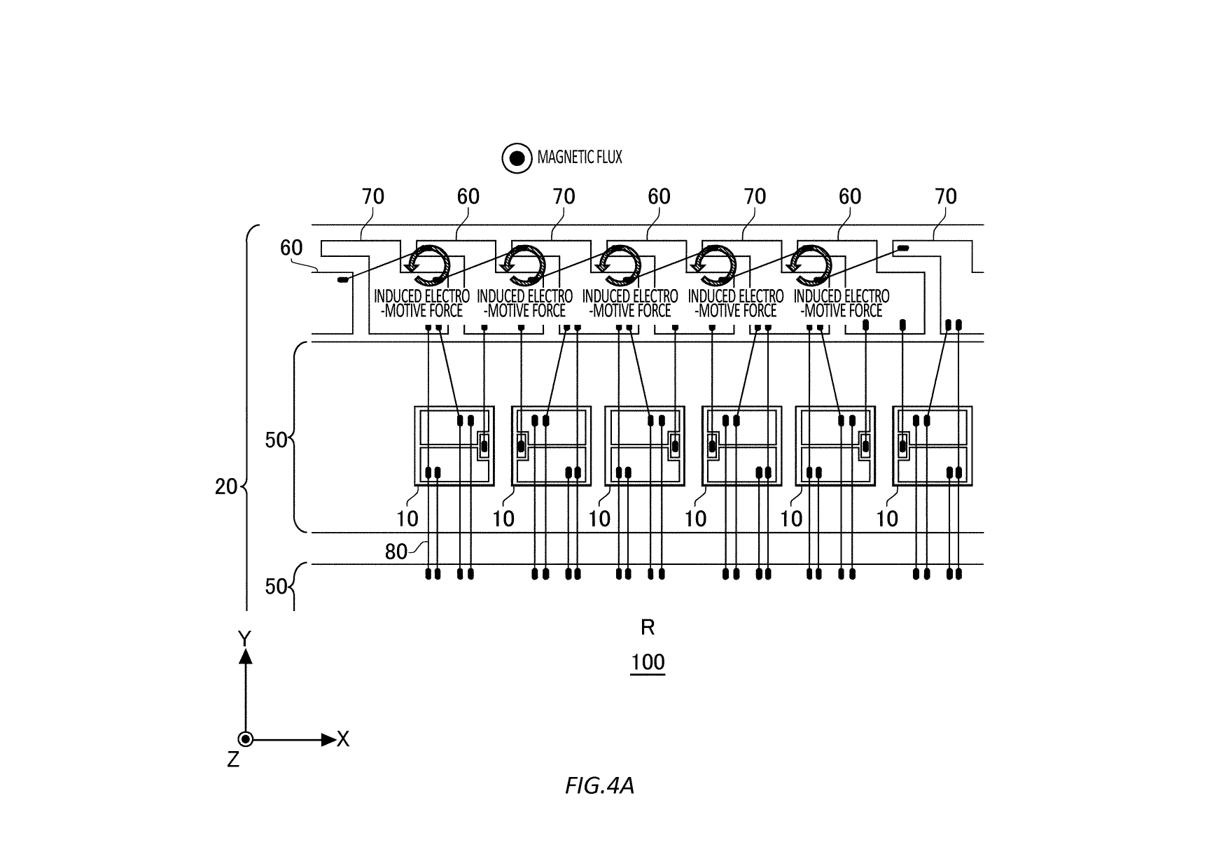

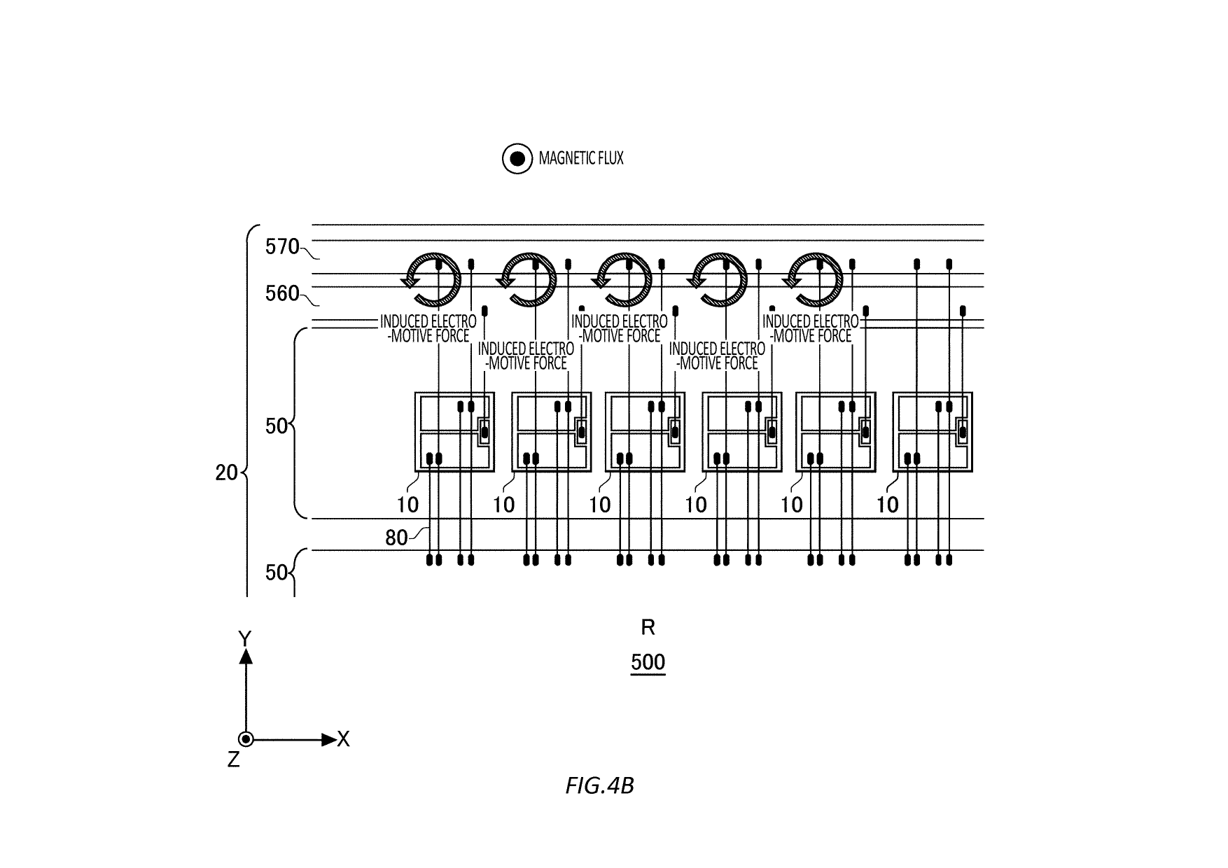

FIG. 4A shows an example of a magnetic flux interlinkage in the semiconductor device 100. For example, when the magnetic flux interlinkage in a +Z axis direction occurs, a counterclockwise induced electromotive force is generated.

In the semiconductor device 100 of the present example, the control signal path including the plurality of first conductive patterns 60 and the control signal path including the plurality of second conductive patterns 70 form a twisted-wire-like current path. As a result, induced electromotive forces in opposite directions are generated in adjacent first conductive patterns 60, and therefore, the induced electromotive forces due to the magnetic flux interlinkage cancel each other out between the adjacent first conductive patterns 60. Similarly, induced electromotive forces cancel each other out between adjacent second conductive patterns 70. Therefore, when magnetic flux interlinks with the control signal path, the induced electromotive forces cancel each other out within the control signal path, thereby making it possible to suppress the influence of the magnetic flux interlinkage.

FIG. 4B shows an example of a magnetic flux interlinkage in the semiconductor device 500 according to a comparative example. For example, when the magnetic flux interlinkage in the +Z axis direction occurs, a counterclockwise induced electromotive force is generated.

In the semiconductor device 500 according to the comparative example, both the first control pattern 560 and the second control pattern 570 are provided to extend, and therefore, an induced electromotive force in one direction is generated as a whole in each of the first control pattern 560 and the second control pattern 570. As a result, the induced electromotive forces are not cancelled out within the control patterns. Therefore, when magnetic flux interlinks with the control signal path, it may not be possible to suppress the influence of the magnetic flux interlinkage.

As described above, in the semiconductor device 100 according to the example, it is possible to reduce parasitic inductance of the current path for controlling the semiconductor element 10 and to suppress the influence of the main current fluctuation and the magnetic flux interlinkage. As a result, the influence of the electromagnetic radiation noise can be suppressed, and the risk of erroneous turn-on of the semiconductor element 10 can also be reduced.

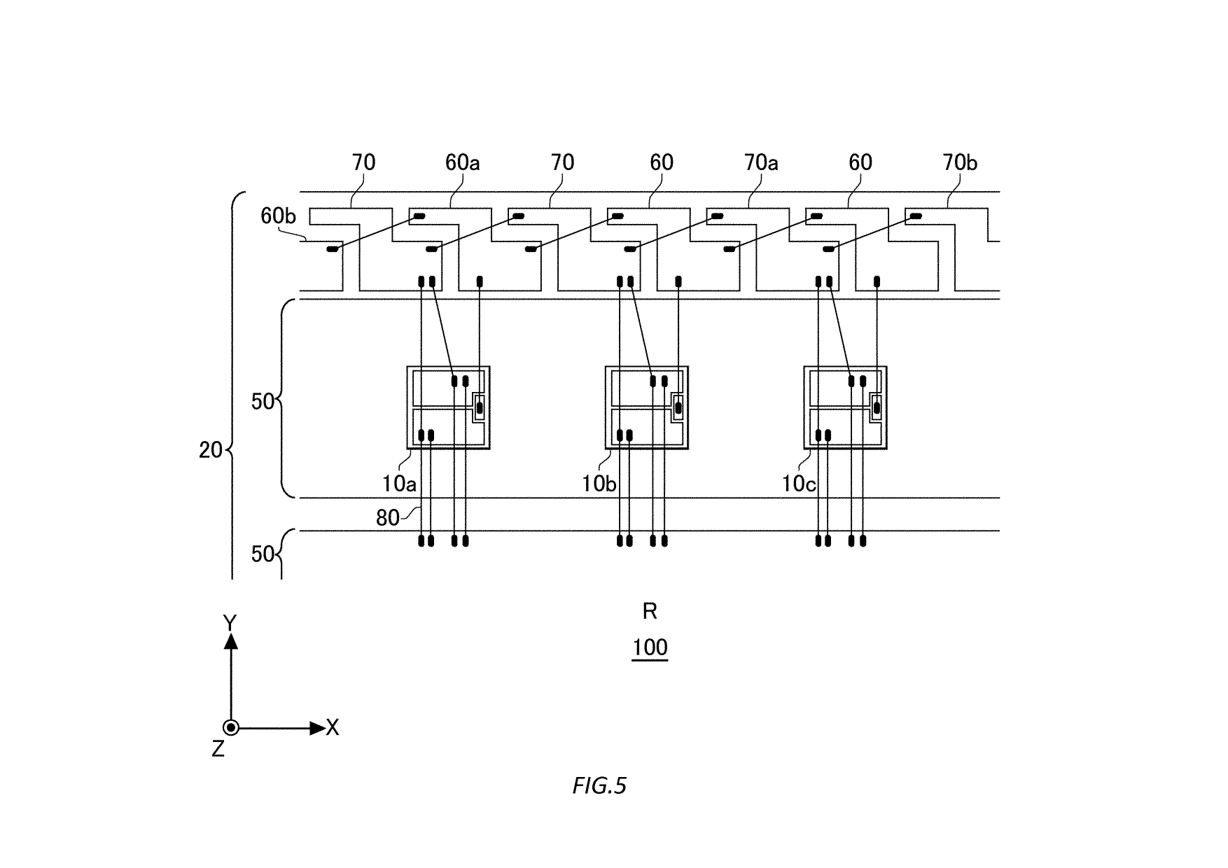

FIG. 5 shows the region R of a modification example of the semiconductor device 100. The semiconductor device 100 of the present example differs from the example of FIG. 1C in that a number of at least one semiconductor element 10 is different. In the present example, the differences with the example of FIG. 1C will be particularly described, and other configurations may be the same as those in the example of FIG. 1C.

The semiconductor element 10 may include a plurality of semiconductor elements 10 arranged in the arrangement direction. Two adjacent semiconductor elements 10 may be non-mirror-symmetrical with respect to the direction orthogonal to the arrangement direction. For example, the semiconductor element 10a and the semiconductor element 10b adjacent to each other are non-mirror-symmetrical with respect to the Y axis direction. The semiconductor element 10b and the semiconductor element 10c adjacent to each other are non-mirror-symmetrical with respect to the Y axis direction.

The plurality of first conductive patterns 60 may include the first conductive pattern 60 to which one semiconductor element 10 is connected. For example, the plurality of first conductive patterns 60 includes the first conductive pattern 60a to which one semiconductor element 10a is connected. The plurality of second conductive patterns 70 may include the second conductive pattern 70 to which one semiconductor element 10 is connected. For example, the plurality of second conductive patterns 70 include the second conductive pattern 70a to which one semiconductor element 10c is connected.

The plurality of first conductive patterns 60 may include the first conductive pattern 60 that is connected to an adjacent first conductive pattern 60 but is not connected to the semiconductor element 10. For example, the plurality of first conductive patterns 60 include the first conductive pattern 60b that is connected to an adjacent first conductive pattern 60a but is not connected to the semiconductor element 10. The plurality of second conductive patterns 70 may include the second conductive pattern 70 that is connected to an adjacent second conductive pattern 70 but is not connected to the semiconductor element 10. For example, the plurality of second conductive patterns 70 include the second conductive pattern 70b that is connected to an adjacent second conductive pattern 70a but is not connected to the semiconductor element 10.

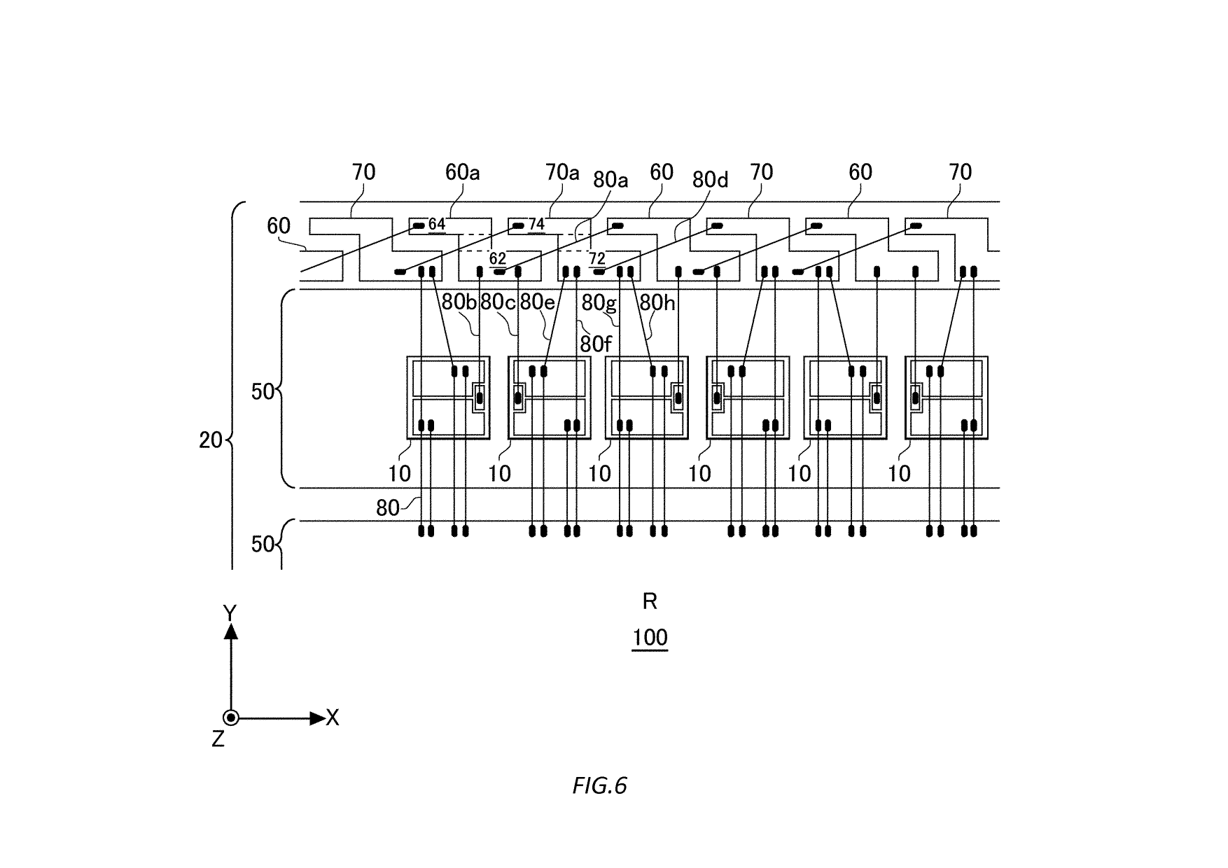

FIG. 6 shows the region R of the modification example of the semiconductor device 100. The semiconductor device 100 of the present example differs from the example of FIG. 1C in that the routing positions of the wire members 80 in the first conductive pattern 60 and the second conductive pattern 70 are different. In the present example, the differences with the example of FIG. 1C will be particularly described, and other configurations may be the same as those in the example of FIG. 1C.

In the first wiring portion 62 of the first conductive pattern 60, an end portion of the wire member 80 for connecting the first conductive patterns 60 to each other and an end portion of the wire member 80 for connecting the first conductive pattern 60 and the semiconductor element 10 may be arranged in the arrangement direction. For example, in the first wiring portion 62 of the first conductive pattern 60a, an end portion of the wire member 80a for connecting the first conductive patterns 60 to each other and end portions of the wire member 80b and the wire member 80c for connecting the first conductive pattern 60a and the semiconductor elements 10 are arranged in the X axis direction.

In the third wiring portion 72 of the second conductive pattern 70, an end portion of the wire member 80 for connecting the second conductive patterns 70 to each other and an end portion of the wire member 80 for connecting the second conductive pattern 70 and the semiconductor element 10 may be arranged in the arrangement direction. For example, in the third wiring portion 72 of the second conductive pattern 70a, an end portion of the wire member 80d for connecting the second conductive patterns 70 to each other and end portions of the wire members 80e to 80h for connecting the second conductive pattern 70a and the semiconductor elements 10 are arranged in the X axis direction.

In the semiconductor device 100 of the present example, an end portion of the wire member 80 for connecting conductive patterns to each other and an end portion of the wire member 80 for connecting a conductive pattern and the semiconductor element 10 are arranged in the arrangement direction. As a result, compared with a case where the end portions are not arranged, the areas of the first wiring portion 62 and the third wiring portion 72 can be reduced respectively, and therefore, further space saving can be achieved.

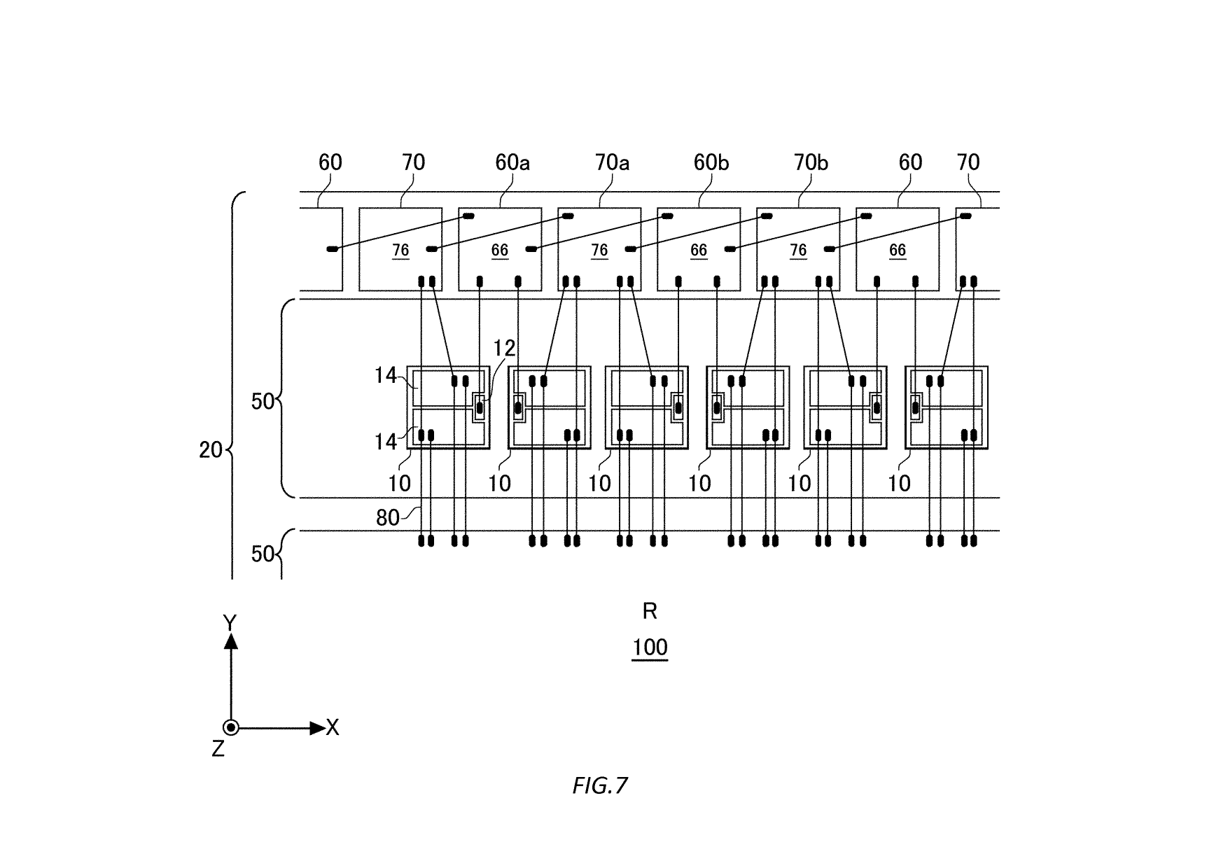

FIG. 7 shows the region R of the modification example of the semiconductor device 100. The semiconductor device 100 of the present example differs from the example of FIG. 1C in that the shapes of the first conductive pattern 60 and the second conductive pattern 70 are different. In the present example, the differences with the example of FIG. 1C will be particularly described, and other configurations may be the same as those in the example of FIG. 1C.

At least one of the plurality of first conductive patterns 60 may have a fifth wiring portion 66 having a substantially quadrangular shape. In the semiconductor device 100 of the present example, each of the first conductive patterns 60 has the fifth wiring portion 66. The wire member 80 for connection to the first control electrode 12 and the wire member 80 for connection to another first conductive pattern 60 may be routed on the fifth wiring portion 66. For example, the wire member 80 for connecting the first conductive pattern 60a to the first control electrode 12 and the wire member 80 for connecting the first conductive pattern 60a to the first conductive pattern 60b, which is another first conductive pattern 60, are routed on the fifth wiring portion 66 of the first conductive pattern 60a.

At least one of the plurality of second conductive patterns 70 may have a sixth wiring portion 76 having a substantially quadrangular shape. In the semiconductor device 100 of the present example, each of the second conductive patterns 70 has the sixth wiring portion 76. The wire member 80 for connection to the second control electrode 14 and the wire member 80 for connection to another second conductive pattern 70 may be routed on the sixth wiring portion 76. For example, the wire member 80 for connecting the second conductive pattern 70a to the second control electrode 14 and the wire member 80 for connecting the second conductive pattern 70a to the second conductive pattern 70b, which is another second conductive pattern 70, are routed on the sixth wiring portion 76 of the second conductive pattern 70a.

For example, configurations described in each of FIGS. 1C and 5 to 7 may be used together with configurations described in other figures. That is, the semiconductor device 100 according to the present invention may include all or any combination of the configurations described in FIGS. 1C and 5 to 7.

As described above, the present invention has been described using embodiments, but the technical scope of the present invention is not limited to the scope described in the above-described embodiments. It is apparent to those skilled in the art that various changes or improvements can be made to the above-described embodiments. It is apparent from the description of the claims that embodiments to which such changes or improvements are made may also be included in the technical scope of the present invention.

It should be noted that an execution order of respective processings such as operations, procedures, steps, and stages in a device, a system, a program, and a method shown in the claims, the specification, and the drawings can be realized in any order unless "before", "prior to", and the like are explicitly stated in particular, and unless an output of a previous processing is used in a subsequent processing. Even if, for convenience, an operation flow in the claims, the specification, and the drawings is described using "first", "next", and the like, this does not mean that performing in this order is essential.

### EXPLANATION OF REFERENCES

10: semiconductor element, 12: first control electrode, 14: second control electrode, 20: insulating plate, 22: lead frame, 32: output terminal, 34: positive electrode terminal, 36: negative electrode terminal, 40: first connection portion, 42: second connection portion, 50: main conductive pattern, 60: first conductive pattern, 62: first wiring portion, 64: second wiring portion, 66: fifth wiring portion, 70: second conductive pattern, 72: third wiring portion, 74: fourth wiring portion, 76: sixth wiring portion, 80: wire member, 100: semiconductor device, 110: casing portion, 120: base portion, 130: external main terminal, 132: external output terminal, 134: external positive electrode terminal, 136: external negative electrode terminal, 140: first external control terminal, 142: second external control terminal.

What is claimed is:

1. A semiconductor device comprising:
an insulating plate;
a semiconductor element provided above the insulating plate and having a first control electrode and a second control electrode;
a plurality of first conductive patterns provided above the insulating plate and electrically connected to the first control electrode; and
a plurality of second conductive patterns provided above the insulating plate and electrically connected to the second control electrode, wherein
the plurality of first conductive patterns and the plurality of second conductive patterns are alternately arranged in a predetermined arrangement direction,
the plurality of first conductive patterns are electrically connected to each other, and
the plurality of second conductive patterns are electrically connected to each other.

2. The semiconductor device according to claim 1, wherein
two adjacent first conductive patterns are connected to each other across a second conductive pattern located between the two adjacent first conductive patterns, and
two adjacent second conductive patterns are connected to each other across a first conductive pattern located between the two adjacent second conductive patterns.

3. The semiconductor device according to claim 1, comprising
a main conductive pattern which extends in the arrangement direction, is provided between the insulating plate and the semiconductor element, and carries a main current of the semiconductor element, wherein
the plurality of first conductive patterns and the plurality of second conductive patterns are adjacent to the main conductive pattern in a direction orthogonal to the arrangement direction.

4. The semiconductor device according to claim 1, wherein
the plurality of first conductive patterns are electrically connected to each other via a wire member, and
the plurality of second conductive patterns are electrically connected to each other via a wire member.

5. The semiconductor device according to claim 4, wherein
the wire member electrically connecting the plurality of first conductive patterns to each other connects two adjacent first conductive patterns by passing above a second conductive pattern located between the two adjacent first conductive patterns, and
the wire member electrically connecting the plurality of second conductive patterns to each other connects two adjacent second conductive patterns by passing above a first conductive pattern located between the two adjacent second conductive patterns.

6. The semiconductor device according to claim 1, wherein
the plurality of first conductive patterns are electrically connected to the first control electrode via a wire member.

7. The semiconductor device according to claim 1, wherein
the plurality of second conductive patterns are electrically connected to the second control electrode via a wire member.

8. The semiconductor device according to claim 1, wherein
at least one of the plurality of first conductive patterns has:
a first wiring portion on which a wire member for connection to the first control electrode is routed; and
a second wiring portion on which a wire member for connection to another first conductive pattern is routed, and
at least one of the plurality of second conductive patterns has:
a third wiring portion on which a wire member for connection to the second control electrode is routed; and
a fourth wiring portion on which a wire member for connection to another second conductive pattern is routed.

9. The semiconductor device according to claim 8, wherein
an area of the second wiring portion is smaller than an area of the first wiring portion, and
an area of the fourth wiring portion is smaller than an area of the third wiring portion.

10. The semiconductor device according to claim 8, wherein
the first wiring portion is closer to the semiconductor element than the second wiring portion is, in a direction orthogonal to the arrangement direction, and
the third wiring portion is closer to the semiconductor element than the fourth wiring portion is, in a direction orthogonal to the arrangement direction.

11. The semiconductor device according to claim 8, wherein
each of two adjacent first conductive patterns has the first wiring portion and the second wiring portion,
the wire member for connection to another first conductive pattern connects the second wiring portion of one of the two adjacent first conductive patterns to the first wiring portion of another of the two adjacent first conductive patterns,
each of two adjacent second conductive patterns has the third wiring portion and the fourth wiring portion, and
the wire member for connection to another second conductive pattern connects the fourth wiring portion of one of the two adjacent second conductive patterns to the third wiring portion of another of the two adjacent second conductive patterns.

12. The semiconductor device according to claim 1, wherein
at least one of the plurality of first conductive patterns has a fifth wiring portion having a substantially quadrangular shape,
a wire member for connection to the first control electrode and a wire member for connection to another first conductive pattern are routed on the fifth wiring portion,
at least one of the plurality of second conductive patterns has a sixth wiring portion having a substantially quadrangular shape, and
a wire member for connection to the second control electrode and a wire member for connection to another second conductive pattern are routed on the sixth wiring portion.

13. The semiconductor device according to claim 1, wherein
the semiconductor element includes a plurality of semiconductor elements arranged in the arrangement direction, and
two adjacent semiconductor elements are non-mirror-symmetrical with respect to a direction orthogonal to the arrangement direction.

14. The semiconductor device according to claim 1, wherein
the semiconductor element includes a plurality of semiconductor elements arranged in the arrangement direction, and
two adjacent semiconductor elements are mirror-symmetrical with respect to a direction orthogonal to the arrangement direction.

15. The semiconductor device according to claim 1, wherein
the semiconductor element includes a plurality of semiconductor elements arranged in the arrangement direction,
the plurality of first conductive patterns include a first conductive pattern to which one semiconductor element is connected, and
the plurality of second conductive patterns include a second conductive pattern to which one semiconductor element is connected.

16. The semiconductor device according to claim 1, wherein
the semiconductor element includes a plurality of semiconductor elements arranged in the arrangement direction,
the plurality of first conductive patterns include a first conductive pattern to which two semiconductor elements are connected, and
the plurality of second conductive patterns include a second conductive pattern to which two semiconductor elements are connected.

17. The semiconductor device according to claim 1, wherein
the plurality of first conductive patterns include a first conductive pattern that is connected to an adjacent first conductive pattern but is not connected to the semiconductor element, and
the plurality of second conductive patterns include a second conductive pattern that is connected to an adjacent second conductive pattern but is not connected to the semiconductor element.

18. The semiconductor device according to claim 1, wherein
the semiconductor element includes a wide bandgap semiconductor.

19. The semiconductor device according to claim 18, wherein
the wide bandgap semiconductor includes any one of silicon carbide semiconductor, gallium nitride semiconductor, or gallium oxide semiconductor.

20. The semiconductor device according to claim 1, comprising:
a first external control terminal electrically connected to the plurality of first conductive patterns;
a second external control terminal electrically connected to the plurality of second conductive patterns; and
an external main terminal electrically connected to a main conductive pattern which carries a main current of the semiconductor element.
